(19) United States
(12) Patent Application Publication
(10) Pub. No.: US 2004/0074770 A1
(43) Pub. Date: Apr. 22, 2004

(54) Rotary target

(76) Inventors: George Wityak, Albuquerque, NM (US); Bruce W. Webb, Albuquerque, NM (US)

Correspondence Address: PEACOCK MYERS AND ADAMS P C, P O BOX 26927, ALBUQUERQUE, NM, 871256927

(21) Appl. No.: 10/614,308

(22) Filed: Jul. 2, 2003

Related U.S. Application Data
(60) Provisional application No. 60/393,547, filed on Jul. 2, 2002.

(51) Int. Cl. C25B 9/00; C23C 14/00

(52) U.S. Cl. 204/298.14; 204/298.01; 204/298.21

(57) ABSTRACT

A rotary target for use in a physical deposition process. The rotary target comprises at least one rotary target segment mechanically disposed on a backing tube.

### CROSS-REFERENCE TO RELATED APPLICATIONS

This application claims the benefit of the filing of U.S. Provisional Patent Application Serial No. 60/393,547, entitled “Rotary Targets for Deposition of Metal Films,” filed on Jul. 2, 2003, and the specification thereof is incorporated herein by reference.

### BACKGROUND OF THE INVENTION

1. Field of the Invention (Technical Field)

The present invention relates to rotary targets preferably used for depositing metal films on selected substrates.

2. Description of Related Art

Note that the following discussion refers to a number of publications by author(s) and year of publication, and that due to recent publication dates certain publications are not to be considered as prior art vis-a-vis the present invention. Discussion of such publications herein is given for more complete background and is not to be construed as an admission that such publications are prior art for patentability determination purposes.

U.S. Pat. No. 4,151,064, entitled “Apparatus for Sputtering Cylinders,” to Kuehnle, issued Apr. 24, 1979, discloses a device for sputtering a coating onto a thin-walled metal sleeve. The device is capable of being configured to form a cylinder or a rigid drum-like member. This device is not a segmented rotary target.

U.S. Pat. No. 4,356,073, entitled “Magnetron Cathode Sputtering Apparatus,” to McKelvey, issued Oct. 26, 1982, discloses a rotatable magnetron cathode sputtering device for operation within an evacuable chamber. The device is for coating substrates that are also contained within said chamber. The cathode is an elongated cylinder, and the sputtered materials are applied on the surface of the cylinder. This device is not segmented, and does not have an adjustable length.

U.S. Pat. No. 4,443,318, entitled “Cathodic Sputtering Apparatus,” to McKelvey, issued Apr. 17, 1984, discloses the use of segmented rectangular targets that are attached longitudinally to a tubular cylinder. The cylinder can be rotated to a specific position relative to the substrate and a different metal deposited. This device does not use cylindrical segments that fit in a sleeve manner.

U.S. Pat. No. 4,445,997, entitled “Rotatable Sputtering Apparatus,” to McKelvey, issued May 1, 1984, discloses an elongated, tubular magnetron cathode for sputter-coating which is contoured longitudinally to provide a non-cylindrical sputtering surface. This device is not segmented, and does not have an adjustable length.

U.S. Pat. No. 5,073,245, entitled “Slotted Cylindrical Hollow Cathode/Magnetron Sputtering Device,” to Hedgcoth, issued Dec. 17, 1991, discloses a hollow, longitudinal cathode with an interior coated wall. This device is designed to deposit film on a planar substrate, has no moving parts and allows for even coating of the cathode. This device is not a segmented rotary target.

U.S. Pat. No. 5,437,778, entitled “Slotted Cylindrical Hollow Cathode/Magnetron Sputtering Device,” to Hedgcoth, issued Aug. 1, 1995, and U.S. Pat. No. 5,529,674, entitled “Slotted Cylindrical Hollow Cathode/Magnetron Sputtering Device,” to Hedgcoth, issued Jun. 25, 1995, disclose a cylindrical target in which the material to be sputtered is positioned in the interior walls of the cylinder. During the sputtering process, a filament or sheet to be coated continuously passes through the interior of the target. These devices do not use segmented cylindrical targets.

U.S. Pat. No. 5,683,558, entitled “Anode Structure for Magnetron Sputtering Systems,” to Sieck et al., issued Nov. 4, 1997, discloses an elongated anode structure having multiple points to attract electrons. In one embodiment of the device, is a magnetron system having a cylindrical cathode and a pair of elongated anodes positioned parallel to and equidistant from the cathode.

Physical vapor deposition, also known as sputtering, is a process whereby ions of an inert gas, such as argon, are electrically accelerated in a high vacuum towards a target of a metal (e.g. an ultrapure metal) or an alloy thereof. The ions physically chip off, or sputter, the target material, which is then deposited as a film on the surface of the substrate. Physical sputtering is the process often involved in the coating of a semiconductor wafer or other substrate mounted within a processing chamber. An inert gas is introduced into the processing chamber and an electric field is applied to ionize the inert gas. The positive ions of the inert gas bombard the target material and dislodge atoms from the target which are subsequently deposited onto the wafer or other substrate in the form of a thin metal film.

The target is held within the deposition chamber by a device called a sputter coating source. The sputter coating source embodies electrical means for biasing the target material structure with a negative voltage, either DC for conductive targets, or RF for non-conductive targets, so the target will attract positive ions from the plasma of an inert gas. The sputter coating source also contains means for cooling the target structure and often magnetic means for containing and enhancing the plasma. One reason for manipulating the heat distribution and/or magnetic field about the target material is to control the uniform depletion of the target material. Otherwise a target tends to wear in one location, thereby causing more down time due to the increase in the replacement of the target within the processing chamber. This, as well as other handling factors, increases operating costs. An alternative or conjunctive solution to the uneven wearing of targets is the use of rotary targets. A rotary target generally comprises a cylinder of a specified metal of specific length and diameter.

Although segmented rotary targets are known in the art, all such targets are formed by joining each half of the segment. In other words, the segments possess the shape of an open clamshell. The two halves are placed about the backing tube and then welded or joined together. Unfortunately, the welding or joining process is the source of unwanted impurities and uneven coatings in such prior targets.

The present invention overcomes the present shortcomings of relatively large rotary targets by utilizing segmented rotary targets. Essentially, rather than forming or casting metal targets in one piece, the targets are formed or cast in segmented, i.e., relatively shorter lengths. The segments are then slipped on or otherwise attached to a backing tube or backing structure, one at a time, until the desired overall length is achieved. Thus, the invention overcomes many of the disadvantages associated with prior rotary targets. The segmented targets also ease the logistical problems associated with handling and shipping long heavy target cylinders.

### BRIEF SUMMARY OF THE INVENTION

The present invention is a rotary target utilized in a physical deposition processing chamber. The rotary target comprises at least one segment rotary target made of metal, ceramic, refractory, alloy, oxide or other suitable material that may be placed on a backing tube to produce a rotary target sized specifically for an application. The rotary target segments may have joints and seams between the segments, and there may also be joints and seams between the rotary target segments and the backing tube. The joints and seams may be, but are not limited to, a square cut, a tapered cut, an interference slip fit, a threaded fit, a compression or locking ring, a lock and key fit, and the like.

The rotary target preferably comprises at least two rotary target segments disposable around a backing tube and disposable in serial position to each other, and a joint between the segmented targets. The rotary target may comprise more than two rotary target segments. Likewise, the rotary target may be a single segment, attachable to the backing tube on site.

The rotary target segments may comprise a metal (e.g. pure metal), a refractory, ceramic, alloy, oxide, and the like. Such materials include, but are not limited to, gold, silver, copper, niobium, tantalum, platinum, palladium, rhodium, iridium, ruthenium, osmium, carbon, silicon, molybdenum, tungsten, vanadium, zirconium, chromium, beryllium, nickel, chrome, nickel-chrome, aluminum, zinc, tin, tin-zinc, zinc-aluminum, high intrinsic value materials and the like. The rotary target segments and joints preferably have substantially little or no impurities.

The rotary target may be any diameter. Preferably, the diameter of the rotary target is between approximately 3 centimeters and approximately 50 centimeters. The rotary target may be any length. Preferably, the length of the rotary target is between approximately 1 foot and approximately 4 meters.

The method and apparatus of disposing the rotary target segments onto the backing tube comprise alternately and in combination mechanical attachment or assembly and disassembly, on-site, included but not limited to the following: a square cut, a tapered cut, an interference slip fit, a threaded fit, a compression ring, a lock and key fit, and the like. The joints and seams of the rotary target preferably comprise smooth joints between the rotary target segments.

The preferred embodiment of the rotary target employs a locking or compression ring for placement of one or more rotary target segments onto the backing tube. The rotary target segment abuts against or slides under a compression ring on the backing tube to secure the rotary target segment. A compression ring assembly, comprising an inner and outer threaded clamshell type ring and hinge, is the preferred embodiment. The inner ring is disposed in a groove of the backing tube for stabilizing the ring assembly. The outer ring threads onto the inner ring, or abuts and goes under the rotary target segment.

In an alternative embodiment the backing tube has an end compression fitting. Preferably the compression fitting is on an end cap that is threaded onto the backing tube. The end cap is removed, the rotary target segment slides onto the backing tube and the end cap is screwed back onto the backing tube.

Another embodiment is the method and apparatus of a lock and key cut between at least one of the rotary target segments and the backing tube or between rotary target segments. The lock and key cut comprises aligning a groove on the backing tube or a segment with a key portion of the rotary target segment.

Threading the rotary target segments onto the backing tube or to each other is another embodiment of the present invention. The backing tube may be threaded along its entire length, along most of its length, along only a portion of its length, or at specific areas of its length (e.g. at an end of each segment). The rotary target segments are then threaded onto the backing tube to create an appropriately sized rotary target.

Another embodiment of the present invention utilizes an interference slip fit method and apparatus. In this embodiment, the rotary target segments have an inner diameter which is slightly smaller and substantially equal to an outside diameter of the backing tube. The rotary target segments are heated or warmed and expanded, and placed or slipped onto the backing tube. The rotary target segments are then cooled to create a tight fit with the backing tube. In another embodiment, the backing tube is cooled and shrunk, and then the rotary target segments are disposed or slipped onto the backing tube. The backing tube is warmed or heated which creates a tight fit between the backing tube and the rotary target segments. In yet another embodiment, the rotary target segments are just slightly larger than the backing tube and are disposed onto the backing tube. Suitable materials which can expand and contract are useful in accordance with the interference slip fit method.

In alternative embodiments, a method and apparatus for disposing the rotary target segments onto the backing tube may cause spaces between the rotary target segments, or the rotary target segments and the backing tube. These spaces maybe filled in accordance with the present invention. These spaces may be backfilled using an adherent or adhesive material. Useful adherent materials preferably comprise a low vapor pressure metal including, but not limited to, indium, silver, and metal alloys. Useful adhesive materials preferably comprise thermally and/or electrically conductive materials.

After the target is spent, it can be removed or disassembled form the backing tube on-site. The backing tube can then be reused with a new rotary target segment assembled thereon.

A primary object of the present invention is to provide a segmented rotary target for depositing metal films on selected substrates. Another object of the present invention is to provide rotary target segments that can be disposed on-site, on a backing tube.

The main advantage of the present invention is that the end user does not have to ship back the backing tube and can reassemble the target on-site. Another advantage of the present invention is the ability to adjust the length of the target, achieve uniform target wear, introduce no impurities and resolve logistical issues present with large rotary targets.

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate several embodiments of the present invention and, together with the description, serve to explain the principles of the invention. The drawings are only for the purpose of illustrating a preferred embodiment of the invention and are not to be construed as limiting the invention. In the drawings:

FIGS. 1a and b are side views of a removable locking ring of the preferred embodiment of the present invention for rotary targets;

FIG. 2 is a side view of a preferred embodiment of FIG. 1;

FIG. 3 is an end view of an inner ring of the FIG. 1 embodiment;

FIG. 4 is a cross-sectional side view of a threaded portion of the inner ring of the FIG. 1 embodiment;

FIG. 5 is an end view of an inner ring hinge of the FIG. 1 embodiment;

FIG. 6 is an end view of the inner ring hinge of the FIG. 5 embodiment;

FIG. 7 is an end view of an outer ring of the FIG. 1 embodiment;

FIG. 8 is a cross-sectional view of the threaded portion of the outer ring of the FIG. 1 embodiment;

FIG. 9 is a side view of an outer ring hinge of the FIG. 1 embodiment;

FIG. 10 is a top view of an outer ring hinge of the FIG. 1 embodiment;

FIG. 11 is a side view of a rotary target with rotary target segments disposed serially on a backing tube;

FIG. 12 is a side view of a rotary target showing a lock and key fit of a rotary target segment disposed on a backing tube;

FIGS. 13a-c illustrate a perspective and end view of an interference slip fit of a rotary target segment disposed on a backing tube;

FIG. 14 is a side view of a rotary target showing a rotary target segment disposed on the backing tube by threading along the entirety of the length of the backing tube; and

FIG. 15 is a side view of a rotary target showing rotary target segments disposed on the backing tube by threading at specific areas of the backing tube.

### DETAILED DESCRIPTION OF THE INVENTION

The present invention is a rotary target useful with a backing or arbor utilized in a physical deposition processing chamber.

In the prior art, the end user or customer usually has to purchase new backing tubes or ship back the old backing tubes to the manufacturer so that the rotary target can be assembled onto and bonded to the backing tube. The present invention offers a huge advantage in that the customer disassembles and removes the spent rotary target segments from the backing tube, needs only to purchase the new rotary target segments, keeps the backing tube, and then can do its own assembly on-site with the new rotary target segments. There are cost savings due to reusable backing tubes and lower shipping costs for just the rotary target segments. With rotary target segments, rather than single rotary targets, the shipping is also easier and less expensive. The assembly and disassembly can be done with simple tools, e.g. spanner wrenches, strap wrenches, etc. No chemical bonding, off-site or on-site, is required. The attachment is done by mechanical means, including but not limited to the various embodiments described herein, such as interference slip fit, compression or locking ring, lock and key, threading, and the like.

As shown in the drawings, rotary target 10 comprises cylinder 12 of a metal, ceramic, refractory, alloy, oxide, and the like. The target metals useful in accordance with the present invention include gold, silver, copper, niobium, tantalum, platinum, palladium, rhodium, iridium, ruthenium, and osmium, carbon, silicon, molybdenum, tungsten, vanadium, zirconium, chromium, beryllium, nickel, chrome, nickel-chrome, aluminum, zinc, tin, tin-zinc, zinc-aluminum, as well as any other metals and other materials, including high intrinsic value materials. This listing is not meant to be comprehensive; other materials may also be used in the present invention.

The overall dimensions of composite target cylinder 12 of the present invention can be any size, but preferably as large as up to 50 centimeters in diameter and up to 4 meters in length and as small as several centimeters in diameter and one foot in length. The target cylinder comprises at least one or more rotary target segments 14, 14′ that are then fitted over backing tube 16 (see FIG. 12) of similar dimension. Joints 18 located between each individual segment may comprise a square cut, a tapered cut (as shown in FIG. 11), a lock and key cut or other joints, depending on the application. The joint should create a smooth transition. Likewise, a seam may also be used referred to as a “joint” in the claims. For example, if a rotary target is to be two meters in length, there are a number of ways to construct the target with that specific dimension from individual rotary target segments. The present invention thus allows that target to either comprise two, one meter segments; four, half meter segments; eight, quarter meter segments, and so on. The stated dimensions are used to describe the present invention, and are not meant to limit the dimensional size of the rotary target of the present invention in any way.

Close Fit and Locking or Compression Ring

In another embodiment (see FIG. 12, right end), rotary target segments 54 are slid onto the backing tube 56. The segment 54 abuts against a step or rim on the backing tube 56. After the last segment 54 is placed upon backing tube 56, a compression fitting 58 is disposed on the opposite end of the backing tube 56, thereby securing the target segments 54 upon the backing tube 56. Seams or joints located between each individual segment should be smooth.

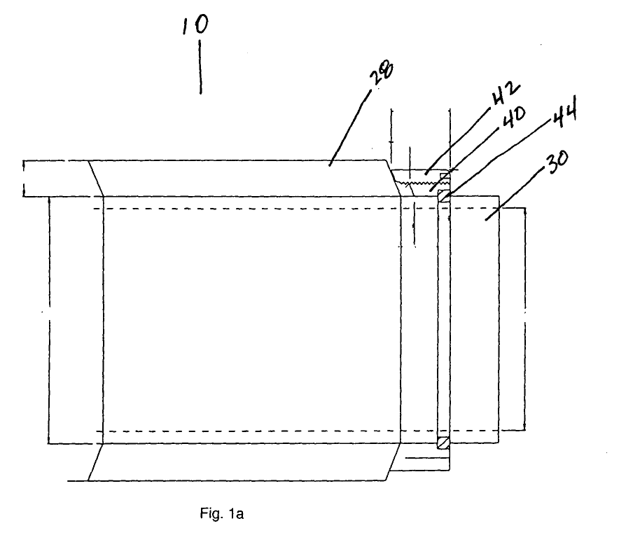

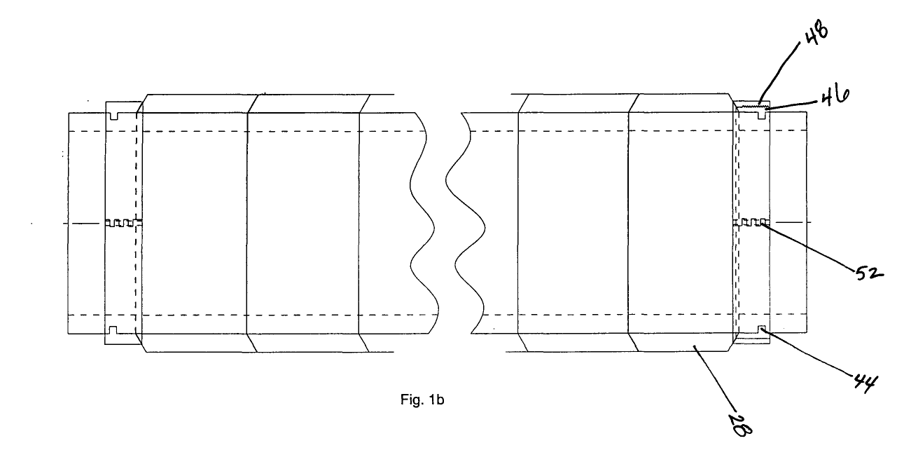

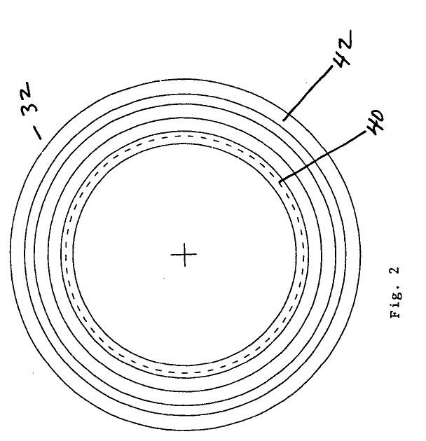

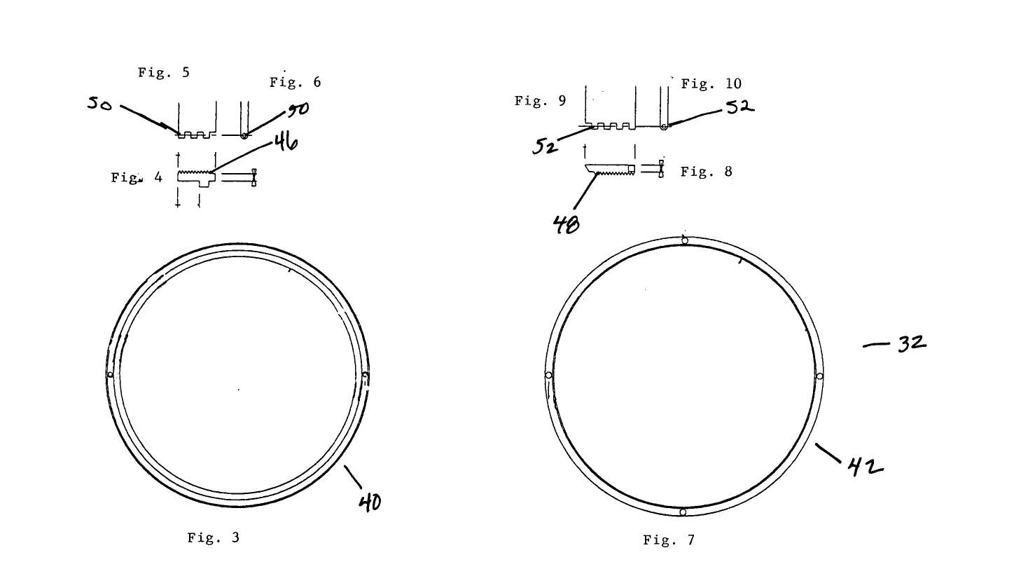

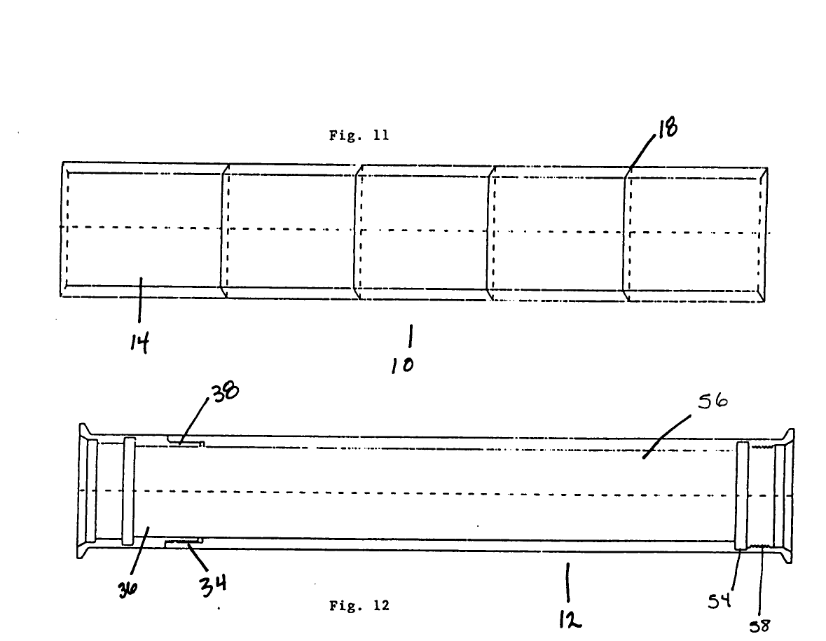

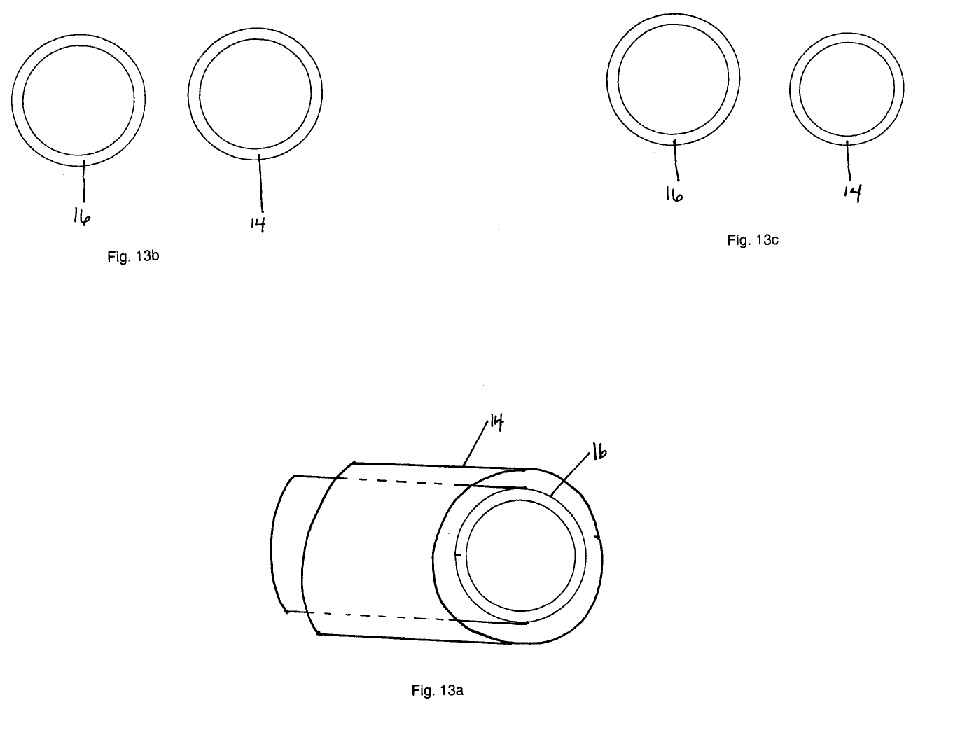

The rotary target segments 28 may also be held by compression or locking fitting 32 between each segment or at the end of backing tube. Compression fitting 32 comprises of inner ring 40 (FIGS. 1-3) and outer ring 42 (FIGS. 1a, 1b, 2 and 7). Inner ring is threaded 46 (FIGS. 1a and 4), and outer ring 42 is cooperatively threaded 48 (FIGS. 1a, 1b and 8). Inner ring 46 is preferably hinged 50 (FIGS. 5 and 6) and outer ring 42 is hinged 52 (FIGS. 9 and 10). Rings 40 and 42 connect in a clamshell fashion, and open opposite hinges 50 and 52. They interconnect with threading 46 on inner ring 40 fitting into threading 48 on outer ring 42. The compression fitting 32 is then disposed on the backing tube 30. (See FIGS. 1a and 1b). FIG. 1b shows the left end of the rotary target which is fixed. The right end of FIG. 1b shows the compression fitting.

The compression fitting may abut the rotary target segment or slide underneath the end of the rotary target segment. Both methods hold the rotary target segment in place on the backing tube.

Interference Slip Fit

As shown in FIGS. 13a-c (diameters exaggerated in drawings to illustrate the expansion), one embodiment of the present invention is to provide a rotary target segment 14, with an inner diameter that is slightly smaller (See FIG. 13c), slightly larger or nearly identical (See FIG. 13b) to the outside diameter 6 of the backing tube. Each cylindrical, rotary target segment 14 is then heated prior to placing rotary target segment 14 on backing tube 16. Heating causes the diameter of the target material to expand slightly (See FIG. 13b). The expanded target segment is slipped over backing tube 16. Upon cooling, the diameter of target segment 14 shrinks, thereby making a very tight fit with backing tube 16 (See FIG. 13a). Alternatively, backing tube 16, usually made from stainless steel or titanium, can be cooled. Target segment 14 material is slipped over smaller diameter backing tube 16. Upon warming, the diameter of backing tube 16 expands, thereby creating a very tight fit with rotary target segment 14. Joints located between each individual segment 14 may comprise a square cut, a tapered cut, a lock and key cut or any other joint or seam preferably to create a smooth transition between segments 14. Materials which have expansion and contraction qualities are useful in accordance with this embodiment.

Threaded Segments

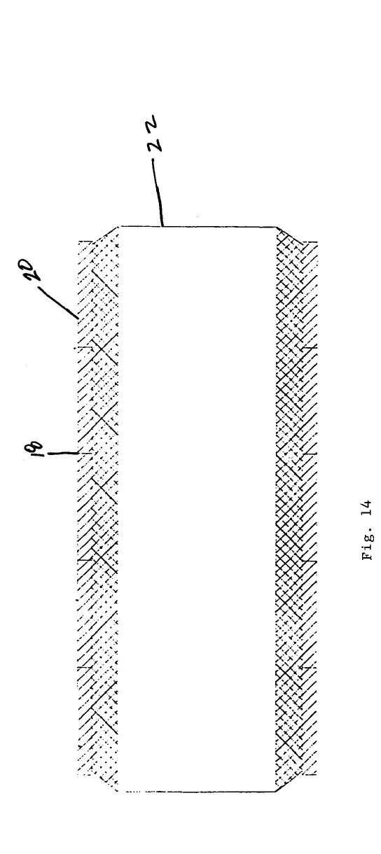

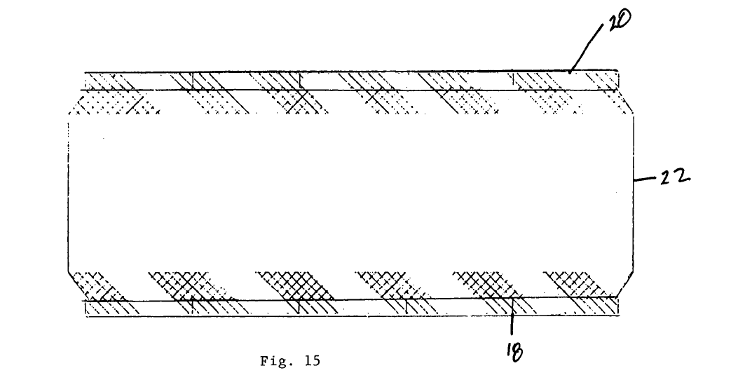

As shown in FIG. 14, another embodiment of the present invention utilizes threading to lock rotary target segment 20 onto backing tube 22. There are a number of ways of using threaded rotary target segment 20 to form rotary target 24. In one embodiment, the outer diameter of backing tube 22 is threaded along its entirety or most of its length (see FIG. 14). Rotary target segment 20 preferably comprises internal threads along the entirety of inner diameter of cylinder 26. Rotary target segment 20 is threaded onto the backing tube 22, much like placing a continuous string of nuts on a threaded bolt.

In a second embodiment, backing tube 22 and rotary target segment 20 are manufactured such that only a portion of both the inner diameter of rotary target segment 20 and the outer diameter of backing tube 22 are threaded in specific coordinated locations. For example, rotary target segment 20 will easily slide along backing tube 22 until a threaded portion of the backing tube 22 is reached. After a couple turns of rotary target segment 20 the threaded portion of rotary target segment 20 reaches the end of the threaded portion on backing tube 22. Rotary target segment 20 is then slid to the next threaded portion and the process repeated until all of the segmented threads align with the threads on backing tube 22.

In each of the two embodiments above, rotary target segments 20 have seams or joints 18 between each individual segment 20.

Lock and Key

In another embodiment, rotary target segment 34 is slid onto backing tube 36 such that at least one groove 38 in backing tube 36 is aligned with at least one key portion of rotary target segment 34, or visa versa. Lock and key groove 38 secures the rotary target segment material along backing tube 36. If multiple rotary target segments are utilized, seams or joints located between each individual segment 34 are smooth.

In each of the embodiments described above, the target cylinder may optionally be secured to the backing tube by means known in the art. These include the use of ductile, low vapor pressure metals such as indium, silver, and alloys thereof, or other securing materials known in the art. Alternatively, the spacing between the target segments and the backing tube may optionally be backfilled with an electrically and/or thermally conductive adhesive, preferably from a metal filled epoxy or other suitable adhesive.

Although the invention has been described in detail with particular reference to these preferred embodiments, other embodiments can achieve the same results. Variations and modifications of the present invention will be obvious to those skilled in the art and it is intended to cover in the appended claims all such modifications and equivalents. The entire disclosures of all references, applications, patents, and publications cited above are hereby incorporated by reference.

What is claimed is:

1. A rotary target for use in physical deposition processing wherein a backing tube is used comprising:
a rotary target segment assembleable on-site and disassembleable on-site onto and from the backing tube; and
a mechanical attachment of the rotary target segment to the backing tube.

2. The rotary target of claim 1 comprising at least two rotary target segments.

3. The rotary target of claim 2 comprising a joint between said rotary target segments.

4. The rotary target of claim 2 wherein said rotary target segments are disposable in serial position to one another.

5. The rotary target of claim 1 wherein said rotary target segment comprises at least one material selected from the group consisting of a pure metal, refractory, ceramic, alloy and oxide.

6. The rotary target of claim 5 wherein said rotary target segment comprises at least one material selected from the group consisting of gold, silver, copper, niobium, tantalum, platinum, palladium, rhodium, iridium, ruthenium, osmium, carbon, silicon, molybdenum, tungsten, vanadium, zirconium, chromium, beryllium, nickel, chrome, nickel-chrome, aluminum, zinc, tin, tin-zinc, zinc-aluminum, and high intrinsic value materials.

7. The rotary target of claim 1 comprising any diameter.

8. The rotary target of claim 7 comprising a diameter of between approximately 3 centimeters and approximately 50 centimeters.

9. The rotary target of claim 1 comprising any length.

10. The rotary target of claim 9 comprising a length of between approximately 1 foot and approximately 4 meters.

11. The rotary target of claim 2 comprising more than two rotary target segments.

12. The rotary target of claim 3 wherein said rotary target segments and said joint have substantially little or no impurities.

13. The rotary target of claim 3 wherein said joint is selected from the group consisting of a square cut and a tapered cut.

14. The rotary target of claim 1 further comprising the backing tube.

15. The rotary target of claim 1 wherein said mechanical attachment comprises a locking assembly.

16. The rotary target of claim 15 wherein said locking ring assembly comprises an outer ring and an inner ring and cooperative threading between said outer ring and said inner ring.

17. The rotary target of claim 15 wherein said rotary target segment abuts against or is disposable over an end said locking ring assembly.

18. The rotary target of claim 16 wherein at least one of said outer ring and said inner ring comprises a clam-shell with a hinge.

19. The rotary target of claim 15 wherein said locking ring assembly is disposable within a groove in the backing tube.

20. The rotary target of claim 1 wherein said mechanical attachment comprises a compression assembly.

21. The rotary target of claim 20 wherein said, compression assembly comprises a threaded end cap on an end of the backing tube.

22. The rotary target of claim 1 wherein said mechanical attachment comprises a lock and key assembly.

23. The rotary target of claim 1 wherein said attachment comprises cooperative threading on said rotary target segment and the backing tube.

24. The rotary target of claim 23 wherein said cooperative threading is along an entire length of said rotary target segment.

25. The rotary target of claim 23 wherein said cooperative threading is along a portion of said rotary target segment.

26. The rotary target of claim 2 comprising a smooth joint between said rotary target segments.

27. The rotary target of claim 14 wherein said mechanical attachment comprises an interference slip fit between said rotary target segment and said backing tube.

28. The rotary target of claim 26 wherein said interference slip fit comprises said rotary target segment comprising an inner diameter slightly smaller to an outside diameter of said backing tube.

29. The rotary target of claim 14 wherein said interference slip fit comprises said rotary target segment comprising an inner diameter substantially equal to an outside diameter of said backing tube.

30. The rotary target of claim 14 further comprising an adherent material between said rotary target segments and said backing tube.

31. The rotary target of claim 14 further comprising an adhesive material between said rotary target segments and said backing tube.

32. The rotary target of claim 31 wherein said adhesive is thermally conductive.

33. The rotary target of claim 31 wherein said adhesive is electrically conductive.

34. A method for on-site mechanical assembly of a rotary target, the method comprising the steps of:
providing at least one rotary target segment;
providing a backing tube; and
mechanically assembling the rotary target segment on the backing tube.

35. The method of claim 34 wherein the steps of providing the rotary target segment and the backing tube comprise providing an inner diameter of the rotary target segment larger than an outside diameter of the backing tube.

36. The method of claim 34 wherein the steps of providing the rotary target segment and the backing tube comprises providing an inner diameter of the rotary target segment slightly smaller than an outside diameter of the backing tube.

37. The method of claim 34 wherein the steps of providing the rotary target segment and the backing tube comprise providing an inner diameter of the rotary target segment nearly equal to an outside diameter of the backing tube.

38. The method of claim 34 wherein the step of mechanically assembling the rotary target segment on the backing tube comprises heating the rotary target segment prior to assembly on the backing tube to expand the rotary target segment.

39. The method of claim 38 wherein the step of mechanically assembling the rotary target segment on the backing tube further comprises the step of slipping the expanded rotary target segment over the backing tube.

40. The method of claim 39 further comprising the step of cooling the rotary target segment disposed on the backing tube, shrinking the rotary target segment and creating a tight fit with the backing tube.

41. The method of claim 34 wherein the step of mechanically assembling the rotary target segment on the backing tube comprises cooling and shrinking the backing tube prior to disposition of the rotary target segment on the backing tube.

42. The method of claim 41 wherein the step of disposing the rotary target segment on the backing tube further comprises the step of slipping the rotary target segment over the backing tube.

43. The method of claim 42 further comprising the step of warming the backing tube, expanding the backing tube and creating a tight fit with the rotary target segment.

44. The method of claim 34 wherein the step of providing at least one rotary target segment comprises providing at least two rotary target segments.

45. The method of claim 44 wherein the step of mechanically assembling the rotary target segments on the backing tube comprises joining the rotary target segments.

46. The method of claim 34 wherein the step of mechanically assembling the rotary target segment on the backing tube comprises using a locking assembly.

47. The method of claim 46 wherein the step of using a locking assembly comprises locking a ring into a groove of the backing tube.

48. The method of claim 46 wherein the step of using a locking assembly comprises using an outer ring and an inner ring.

49. The method of claim 49 wherein the step of using an outer ring and an inner ring comprises using cooperative threading between the inner ring and the outer ring.

50. The method of claim 46 wherein the step of using a locking assembly comprises abutting the locking assembly against the rotary target segment.

51. The method of claim 46 wherein the step of using a locking assembly comprises disposing the rotary target segment over an end of the locking assembly.

52. The method of claim 34 wherein the step of mechanically assembling the rotary target segment on the backing tube comprises threading the rotary target segment onto the backing tube.

53. The method of claim 52 wherein the step of threading comprises threading along an entirety of the backing tube.

54. The method of claim 52 wherein the step of threading comprises threading along a portion of the backing tube.

55. The method of claim 34 wherein the step of mechanically assembling the rotary target segment onto the backing tube comprises using a lock and key assembly.

56. The method of claim 45 wherein the step of joining the rotary target segments comprises joining at least some ends of the rotary target segments with at least one joint selected from the group consisting of a square cut, tapered cut, smooth joint and seam.

57. The method of claim 34 further comprising the step of backfilling between the rotary target segment and the backing tube.

58. The method of claim 57 wherein the step of backfilling comprises backfilling with an adhesive material.

59. The method of claim 58 wherein the step of backfilling comprises backfilling with an electrically conductive adhesive.

60. The method of claim 59 wherein the step of backfilling comprises backfilling with a thermally conductive adhesive.

61. The method of claim 57 wherein the step of backfilling comprises backfilling with an adherent material.

62. The method of claim 61 wherein the step of backfilling further comprises backfilling with an adherent low vapor pressure metal.

63. The method of claim 61 wherein the step of backfilling comprises backfilling with at least one material selected from the group consisting of indium, silver, and metal alloys.

64. The method of claim 34 further comprising the step of dissembling on-site the rotary target segment from the backing tube after the rotary target segment is spent.

65. The method of claim 64 further comprising the step of reusing the backing tube with a new rotary target segment.

66. The method of claim 34 wherein the step of mechanically assembling the rotary target segment on the backing tube comprises using a compression fitting.

67. The method of claim 66 wherein the step of using a compression fitting comprises of using an end cap on the backing tube.

68. The method of claim 67 wherein the step of using an end cap on the backing tube comprises threading on the end cap, sliding the rotary target segment onto the backing tube, and screwing the end cap onto the backing tube, and abutting against the rotary target segment.
